(19) United States
(12) Patent Application Publication
(10) Pub. No.: US 2024/0343280 A1
(43) Pub. Date: Oct. 17, 2024

(54) Article Transport Facility

(71) Applicant: Daifuku Co., Ltd., Osaka-shi (JP)

(72) Inventor: Kengo Ikedo, Komaki-shi (JP)

(21) Appl. No.: 18/636,358

(22) Filed: Apr. 16, 2024

(30) Foreign Application Priority Data
Apr. 17, 2023 (JP) 2023-067260

(51) Int. Cl. B61L 27/16; H01L 21/677

(52) U.S. Cl. CPC B61L 27/16; H01L 21/67727; H01L 21/6773

(57) ABSTRACT

A travel path includes a primary path and a bypass path including at least fewer stations or fewer path intersecting portions than the primary path per unit distance. A control device selects, using a path cost including a distance cost being higher for a greater distance by which article transport vehicles move and a structure cost being higher for a slower speed at which the article transport vehicles move based on a structure of the travel path, a route having the lowest path cost from multiple candidate routes along which a target vehicle is movable from a departure point to a destination point. The control device adjusts, when a predetermined determination condition is satisfied in selecting the route, the path cost of a candidate route following the bypass path to be lower than a path cost used when the predetermined determination condition is unsatisfied.

### CROSS-REFERENCE TO RELATED APPLICATION

This application claims priority to Japanese Patent Application No. 2023-067260 filed Apr. 17, 2023, the disclosure of which is hereby incorporated by reference in its entirety.

### BACKGROUND OF THE INVENTION

### Field of the Invention

The present invention relates to an article transport facility including multiple article transport vehicles and a control device. The multiple article transport vehicles move along a predefined travel path along which the article transport vehicles can move to transport articles. The control device controls the article transport vehicles.

### Description of Related Art

An example of such an article transport facility is described in Japanese Unexamined Patent Application Publication No. 2019-080411. The article transport facility in Japanese Unexamined Patent Application Publication No. 2019-080411 includes a control device that sets a route for moving an article transport vehicle from a departure point to a destination point on a travel path.

The article transport facility in Japanese Unexamined Patent Application Publication No. 2019-080411 may include multiple candidate routes for a route from the departure point of the article transport vehicle to the destination point. In this case, a known method selects a candidate route with the lowest cost from the multiple candidate routes. The cost is set based on, for example, the distance and the structure of a path.

With this method, however, the article transport vehicle may reach the destination point in a shorter period of time along an unselected candidate route depending on a situation of the travel path on which multiple article transport vehicles are moving. Thus, setting routes based on an inflexible criterion may cause an inappropriate route to be selected from the multiple candidate routes, possibly decreasing the article transport efficiency of the entire article transport facility.

### SUMMARY OF THE INVENTION

An article transport facility that can select an appropriate route from multiple candidate routes to facilitate the article transport efficiency is awaited in view of the foregoing.

In response to this, an article transport facility according to an aspect includes a plurality of article transport vehicles that move along a travel path predefined to transport articles, and a control device that controls the plurality of article transport vehicles. The travel path includes a primary path and a bypass path. The primary path includes a plurality of stations at which the plurality of article transport vehicles stop, and a plurality of path intersecting portions in which paths intersect. The bypass path is connected to the primary path at a plurality of joints set on the primary path. The control device selects, using a path cost including a distance cost being higher for a greater distance by which the plurality of article transport vehicles move and a structure cost being higher for a slower speed at which the plurality of article transport vehicles move based on a structure of the travel path, a candidate route having the path cost being lowest from a plurality of candidate routes along which a target vehicle being one of the plurality of article transport vehicles is movable from a departure point to a destination point on the travel path. The control device adjusts, when a predetermined determination condition is satisfied in selecting the candidate route, the path cost of a candidate route of the plurality of candidate routes following the bypass path to be lower than a path cost used when the predetermined determination condition is unsatisfied.

With the structure according to the above aspect, when the predetermined determination condition is satisfied, a candidate route following the bypass path is more likely to be selected as a route for moving the target vehicle from the departure point to the destination point. This increases the number of article transport vehicles traveling on the bypass path when, for example, more article transport vehicles can travel on the primary path, and the article transport vehicles are more likely to be distributed on the primary path and the bypass path. Thus, this structure allows selection of an appropriate route from the plurality of candidate routes, and facilitates the article transport efficiency of the entire article transport facility.

### BRIEF DESCRIPTION OF THE DRAWINGS

FIG. 1 is a schematic diagram of an article transport facility according to an embodiment, showing its overall structure.

FIG. 2 is a control block diagram of the article transport facility according to the embodiment.

FIG. 3 is a diagram showing example candidate routes.

FIG. 4 is a diagram showing an example path cost.

FIG. 5 is a flowchart of an example route selection process.

### DESCRIPTION OF THE INVENTION

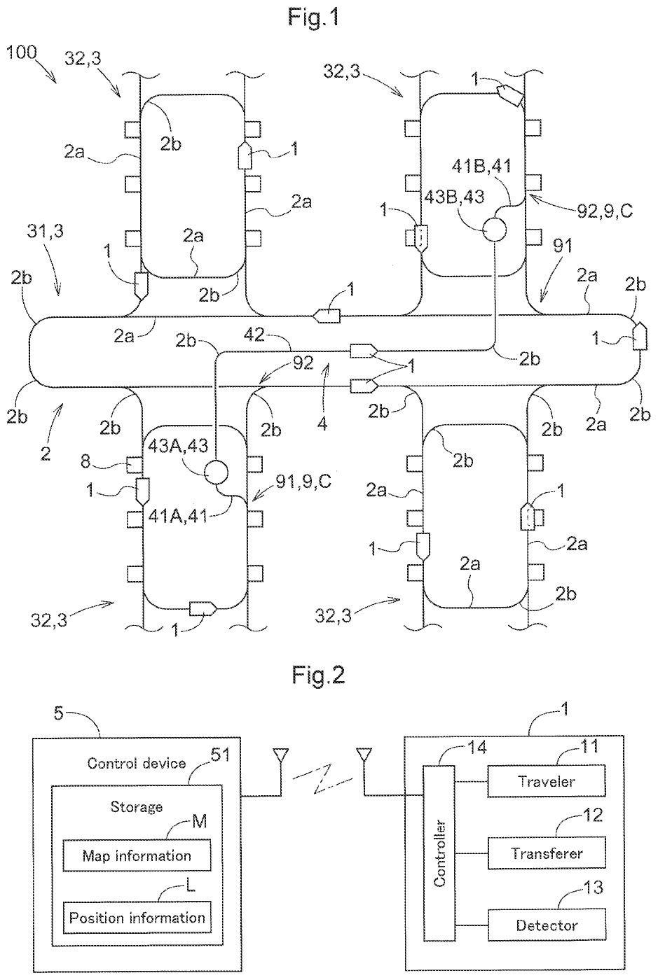

An article transport facility 100 according to an embodiment will be described below with reference to the drawings. As shown in FIG. 1, the article transport facility 100 includes multiple article transport vehicles 1 that transport articles along a predefined travel path 2 along which the article transport vehicles 1 can move. In the present embodiment, the travel path 2 includes a rail hung from the ceiling. In other words, the article transport vehicles 1 are ceiling-hung transport vehicles in the present embodiment. The article transport vehicles 1 transport, for example, front opening unified pods (FOUPs) containing semiconductor substrates as articles.

The travel path 2 includes both straight portions 2a each in the form of a straight line and curved portions 2b each in the form of a curved line. The travel path 2 includes multiple stations 8 and multiple path intersecting portions 9.

The stations 8 allow the article transport vehicles 1 to stop at positions corresponding to the stations 8 and to, for example, transfer an article to and from the article transport vehicles 1. At each station 8, an article is transferred to and from, for example, a load port of a processing device that processes the article, a loading and unloading port of a storage device for storing the article, or a storage shelf for temporarily storing the article.

The path intersecting portions 9 are intersections of multiple paths. The path intersecting portions 9 include branching portions 91 in which a path branches into multiple paths and joining portions 92 in which multiple paths join one another. In the present embodiment, a straight portion 2a and a curved portion 2b are connected to each other in each of the branching portions 91 and the joining portions 92.

The travel path 2 includes a primary path 3 and a bypass path 4. The bypass path 4 is connected to the primary path 3 at multiple joints C set on the primary path 3. The joints C are the path intersecting portions 9 in which the primary path 3 intersects with the bypass path 4. More specifically, the branching portions 91 in which the bypass path 4 branches from the primary path 3 and the joining portions 92 in which the bypass path 4 joins the primary path 3 are joints C.

The bypass path 4 includes at least fewer stations 8 or fewer path intersecting portions 9 per unit distance than the primary path 3. In the present embodiment, the bypass path 4 includes no station 8. In other words, being fewer than a specific target of comparative includes being zero.

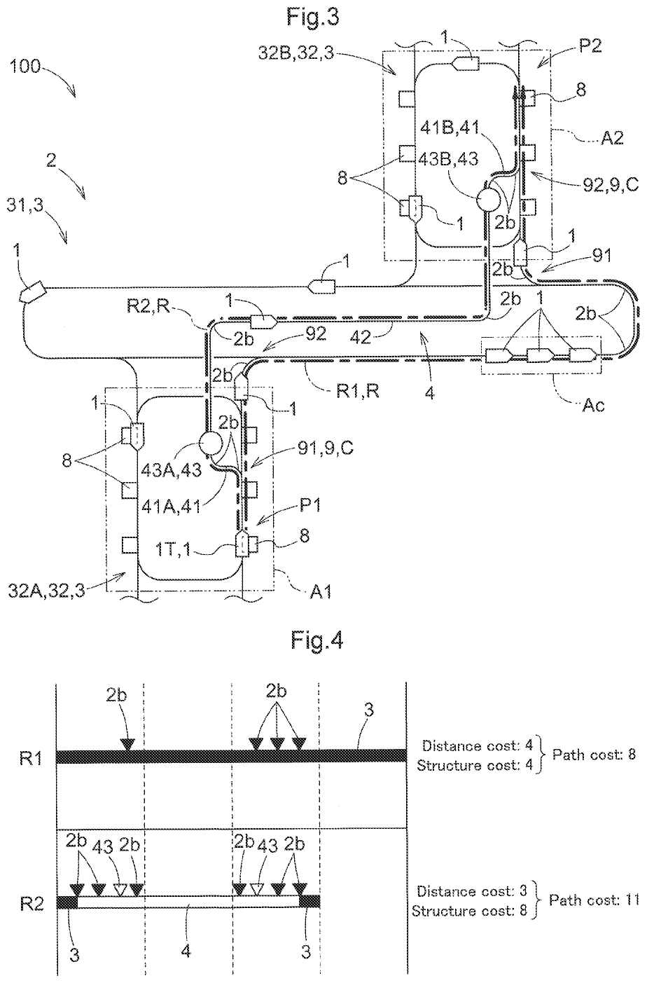

In the present embodiment, the primary path 3 includes a first path 31 and multiple second paths 32 connected to the first path 31. The first path 31 and the second paths 32 are annular. In the present embodiment, the multiple second paths 32 each include multiple stations 8, and the first path 31 includes no station 8. In the present embodiment, the bypass path 4 is located to connect two second paths 32. In the example shown in FIG. 1, four second paths 32 are connected to the first path 31. The four second paths 32 each include six stations 8. In FIG. 1, each article transport vehicle 1 is shown as a pentagon with a tip protruding in a direction in which the article transport vehicle 1 travels. The same applies in FIG. 3.

In the present embodiment, the primary path 3 is entirely set at the same height. The bypass path 4 includes a first layer path 41 installed at a first height equal to the height at which the primary path 3 is set, a second layer path 42 installed at a second height different from the first height, and lifters 43 for lifting and lowering the article transport vehicles 1 between the first height and the second height. In the present embodiment, the second height is higher than the first height. In other words, the bypass path 4 extends through a higher position than the primary path 3 in the present embodiment.

In this example, the bypass path 4 includes a first portion 41A and a second portion 41B as a pair of portions of the first layer path 41, the second layer path 42, and a first lifter 43A and a second lifter 43B as a pair of lifters 43.

The first portion 41A of the first layer path 41 is connected to the second path 32 in the primary path 3, forming the branching portion 91 in which the bypass path 4 branches from the second path 32. In the present embodiment, the first portion 41A of the first layer path 41 includes two curved portions 2b. The second portion 41B of the first layer path 41 is connected to the second path 32 in the primary path 3, forming the joining portion 92 in which the bypass path 4 joins the second path 32. In the present embodiment, the second portion 41B of the first layer path 41 includes two curved portions 2b.

In the present embodiment, the second layer path 42 includes two curved portions 2b.

The first lifter 43A is a lifter 43 for lifting the article transport vehicles 1 from the first portion 41A of the first layer path 41 to the second layer path 42. The second lifter 43B is a lifter 43 for lowering the article transport vehicles 1 from the second layer path 42 to the second portion 41B of the first layer path 41.

As shown in FIG. 2, the article transport facility 100 includes a control device 5 that controls the article transport vehicles 1. In the present embodiment, each article transport vehicle 1 includes a traveler 11, a transferer 12, a detector 13, and a controller 14.

The traveler 11 includes multiple wheels that roll on a rail included in the travel path 2. With a driving force from a travel motor, at least one of the multiple wheels rolls on the rail to cause the traveler 11 to travel along the travel path 2.

The transferer 12 transfers an article to and from a predetermined transfer site (e.g., station 8). Although not described in detail, the transferer 12 includes, for example, a holder for holding an article and a lift portion for lifting and lowering the holder relative to the traveler 11. The transferer 12 also includes a horizontal mover that moves the holder horizontally relative to the traveler 11 and a rotator that rotates the holder about a rotation axis in a vertical direction relative to the traveler 11 as appropriate. The transferer 12 may have any structure appropriate for transferring an article to and from the transfer site and is not limited to the structure described above.

The detector 13 can detect multiple detectable members (not shown) installed along the travel path 2 and can read position information L stored in the detectable members. The position information L represents positions at which detectable members storing the position information L are installed. The detectable members can include, for example, barcodes or wireless tags. For detectable members including barcodes, the detector 13 may be a barcode reader. For detectable members including wireless tags, the detector 13 may be a tag reader.

The controller 14 controls the traveler 11 and the transferer 12 in response to a command from the control device 5. The controller 14 transmits the position information L read by the detector 13 to the control device 5.

In the present embodiment, the control device 5 includes a storage 51 storing various items of information. The storage 51 stores the position information L transmitted from the controller 14. The storage 51 prestores map information M representing the structure of the travel path 2.

As shown in FIG. 3, the control device 5 extracts multiple candidate routes R along which a target vehicle 1T being one of the article transport vehicles 1 can move from a departure point P1 to a destination point P2 on the travel path 2. In the present embodiment, the departure point P1 is set as one of the stations 8 located on a first one of the two second paths 32 connected to each other with the bypass path 4. The destination point P2 is set as one of the stations 8 located on a second one of the two second paths 32 connected to each other with the bypass path 4.

In FIG. 3, among the multiple second paths 32, two second paths 32 including the departure point P1 and the destination point P2 alone are shown for ease of explanation. Hereafter, the second path 32 including the departure point P1 is a departure path 32A, and the second path 32 including the destination point P2 is a destination path 32B.

In the present embodiment, the control device 5 extracts a first route R1 and a second route R2 as multiple candidate routes R as described herein. The first route R1 is a candidate route R following the primary path 3 alone without following the bypass path 4. The second route R2 is a candidate route R following both the primary path 3 and the bypass path 4.

In the present embodiment, the first route R1 follows the departure path 32A, the joining portion 92 in which the departure path 32A joins the first path 31, the first path 31, the branching portion 91 in which the destination path 32B branches from the first path 31, and the destination path 32B in this order from the departure point P1 to the destination point P2.

In the present embodiment, the second route R2 follows the departure path 32A in the primary path 3, the first portion 41A of the first layer path 41, the first lifter 43A, the second layer path 42, the second lifter 43B, the second portion 41B of the first layer path 41 in the bypass path 4, and the destination path 32B in the primary path 3 in this order from the departure point P1 to the destination point P2.

The control device 5 performs a route selection process for selecting a candidate route R with a lowest path cost from the multiple candidate routes R. The path cost is determined as a cost at which the target vehicle 1T moves from the departure point P1 to the destination point P2. The path cost includes a distance cost and a structure cost.

The distance cost is higher for a greater distance by which the article transport vehicles 1 move. In the example shown in FIG. 4, the target vehicle 1T on the second route R2 moves by a distance that is three-fourth of the distance by which the target vehicle 1T on the first route R1 moves. Thus, the first route R1 has a distance cost of 4, and the second route R2 has a distance cost of 3. In FIG. 4, the solid horizontal bars indicate the distances of the primary path 3 on the first route R1 and on the second route R2. The outlined horizontal bar indicates the distance of the bypass path 4 on the second route R2.

The structure cost is higher for a slower speed at which the article transport vehicles 1 move based on the structure (e.g., shape) of the travel path 2. In the present embodiment, the structure cost includes a cost reflecting a slower moving speed of the article transport vehicles 1 entering the curved portions 2b and a cost reflecting a slower moving speed of the article transport vehicles 1 being lifted and lowered by the lifters 43.

As shown in FIG. 3, the first route R1 passes a curved portion 2b in the joining portion 92 in which the departure path 32A joins the first path 31, two curved portions 2b in the first path 31, and a curved portion 2b in the branching portion 91 in which the destination path 32B branches from the first path 31, or in other words, four curved portions 2b in total.

The second route R2 passes two curved portions 2b in the first portion 41A of the first layer path 41, two curved portions 2b in the second layer path 42, and two curved portions 2b in the second portion 41B of the first layer path 41, or in other words, six curved portions 2b in total. Additionally, the second route R2 passes the first lifter 43A and the second lifter 43B, or in other words, two lifters 43 in total.

Thus, in the example shown in FIG. 4, the first route R1 has a structure cost of 4, and the second route R2 has a structure cost of 8. In FIG. 4, the solid triangles indicate the curved portions 2b. The outlined triangles indicate the lifters 43.

In the example shown in FIG. 4, the first route R1 and the second route R2 each have a path cost being the sum of the distance cost and the structure cost. Thus, the first route R1 has a path cost of 8, and the second route R2 has a path cost of 11.

In this case, the route selection process normally selects a candidate route R with a lowest path cost from the multiple candidate routes R, thus selecting the first route R1. However, when predetermined determination conditions are satisfied, the control device 5 performs, in the route selection process, a cost adjustment process for adjusting the path cost of a candidate route R following the bypass path 4 to be lower than the path cost used when the determination conditions are unsatisfied.

In the cost adjustment process in the present embodiment, the path cost of the candidate route R following the bypass path 4 is reduced by a predetermined proportion, or in other words, the path cost of the candidate route R following the bypass path 4 is multiplied by a predefined decimal (e.g., 0.7). In the example shown in FIG. 4, multiplying the path cost 11 of the second route R2 by 0.7 produces 7.7, which is less than the path cost 8 of the first route R1. In the route selection process, the second route R2 is then selected as a candidate route R with a lowest path cost.

In the present embodiment, the determination conditions include first to fourth conditions described below.

The first condition is that a movement distance index is greater than or equal to a predetermined first threshold. The movement distance index is an index of the distance by which the article transport vehicles 1 move from the departure point P1 to the destination point P2. In the present embodiment, the movement distance index is the distance by which the article transport vehicles 1 move along a candidate route R following the primary path 3 alone and having the lowest path cost. In this example, the movement distance index is the distance by which the article transport vehicles 1 move along the first route R1 that is a candidate route R following the primary path 3 alone and being shortest.

The second condition is that the number of article transport vehicles 1 on the bypass path 4 is less than or equal to a predetermined second threshold.

The third condition is that at least a part of the candidate route R following the primary path 3 alone and having the lowest path cost is congested with the article transport vehicles 1 or that the number of article transport vehicles 1 on the candidate route R is greater than or equal to a predetermined third threshold. In the example shown in FIG. 3, the candidate route R following the primary path 3 alone and having the lowest path cost is the first route R1. A congested area Ac on the first route R1 is congested with three article transport vehicles 1.

The fourth condition is that the combination of a departure area A1 including the departure point P1 and a destination area A2 including the destination point P2 is a preset combination. In the present embodiment, the departure area A1 includes an entire portion of the departure path 32A, and the destination area A2 includes an entire portion of the destination path 32B. The combination of the departure area A1 and the destination area A2 may be manually set as appropriate or may be automatically set based on the structure of the travel path 2.

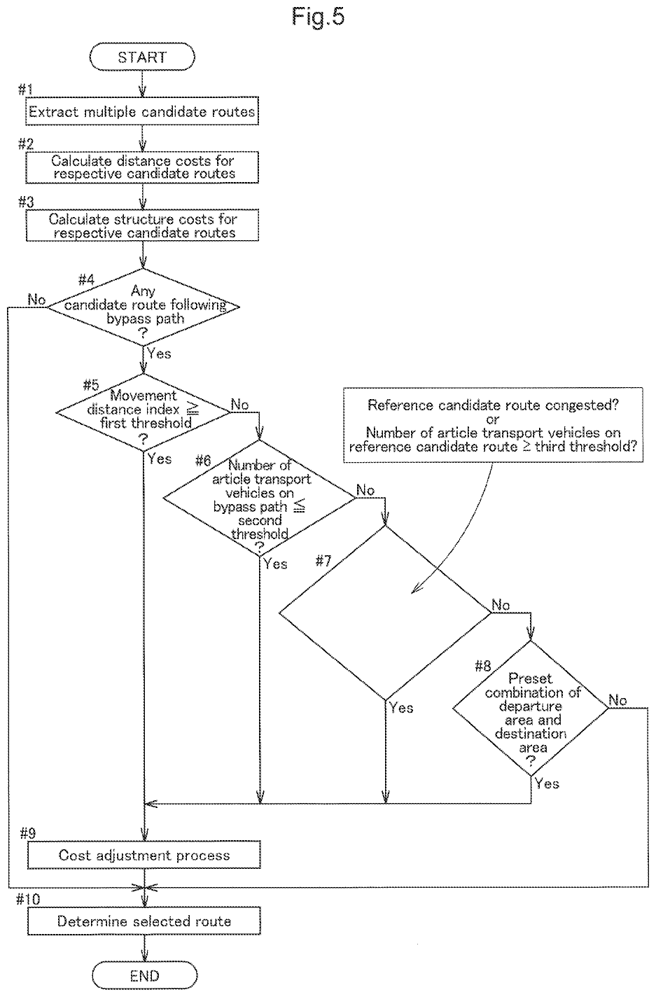

FIG. 5 is a flowchart of an example route selection process performed by the control device 5. As shown in FIG. 5, the control device 5 first extracts multiple candidate routes R along which the target vehicle 1T as one of the article transport vehicles 1 can move from the departure point P1 to the destination point P2 on the travel path 2 (step 1).

The control device 5 then calculates distance costs for the respective candidate routes R (step 2). The control device 5 calculates structure costs for the respective candidate routes R (step 3).

Subsequently, the control device 5 determines whether the multiple candidate routes R include a candidate route R following the bypass path 4 (step 4). When the multiple candidate routes R include a candidate route R following the bypass path 4 (Yes in step 4), the control device 5 determines whether the movement distance index is greater than or equal to the predetermined first threshold, or in other words, whether the first condition is satisfied (step 5).

When the movement distance index is greater than or equal to the first threshold (Yes in step 5), the control device 5 performs the cost adjustment process as described above (step 9).

When the movement distance index is less than the first threshold (No in step 5), the control device 5 determines whether the number of article transport vehicles 1 on the bypass path 4 is less than or equal to the predetermined second threshold, or in other words, whether the second condition is satisfied (step 6).

When the number of article transport vehicles 1 on the bypass path 4 is less than or equal to the second threshold (Yes in step 6), the control device 5 performs the cost adjustment process as described above (step 9).

When the number of article transport vehicles 1 on the bypass path 4 is greater than the second threshold (No in step 6), the control device 5 determines whether at least a part of the candidate route R following the primary path 3 alone and having the lowest path cost (hereafter referred to as the reference candidate route) is congested with the article transport vehicles 1 or whether the number of the article transport vehicles 1 on the reference candidate route is greater than or equal to the predetermined third threshold, or in other words, whether the third condition is satisfied (step 7).

When at least a part of the reference candidate route is congested with the article transport vehicles 1 or when the number of article transport vehicles 1 on the reference candidate route is greater than or equal to the third threshold (Yes in step 7), the control device 5 performs the cost adjustment process as described above (step 9).

When the reference candidate route is not congested with the article transport vehicles 1 and the number of article transport vehicles 1 on the reference candidate route is less than the third threshold (No in step 7), the control device 5 determines whether the combination of the departure area A1 and the destination area A2 is the preset combination, or in other words, whether the fourth condition is satisfied (step 8).

When the combination of the departure area A1 and the destination area A2 is the preset combination (Yes in step 8), the control device 5 performs the cost adjustment process as described above (step 9).

After the cost adjustment process (step 9), the control device 5 selects a candidate route R with the lowest path cost as a selected route from the multiple candidate routes R (step 10).

When the extracted multiple candidate routes R do not include a candidate route R following the bypass path 4 (No in step 4) or when the combination of the departure area A1 and the destination area A2 is not the preset combination (No in step 8), the control device 5 selects a candidate route R with the lowest path cost as a selected route from the multiple candidate routes R (step 10) without performing the cost adjustment process in step 9.

### Other Embodiments

(1) In the above embodiments, the determination conditions include the first to fourth conditions in the route selection process, in which the determination as to whether the first condition is satisfied (step 5), the determination as to whether the second condition is satisfied (step 6), the determination as to whether the third condition is satisfied (step 7), and the determination as to whether the fourth condition is satisfied (step 8) are performed in this order. The determinations may be performed in any order. The determination conditions may simply include one, two, or three of the first to fourth conditions.
(2) In the above embodiments, the bypass path 4 includes no station 8. In some embodiments, the bypass path 4 may include a station 8.
(3) In the above embodiments, the second height at which the second layer path 42 in the bypass path 4 is installed is higher than the first height at which the primary path 3 is set, or in other words, the bypass path 4 extends through a higher position than the primary path 3. In some embodiments, the second height may be lower than the first height, or in other words, the bypass path 4 may extend through a lower position than the primary path 3. In some embodiments, the first height may be equal to the second height, or in other words, the bypass path 4 may be installed entirely at the same height as the primary path 3.
(4) In the above embodiments, the bypass path 4 includes the first layer path 41, the second layer path 42, and the lifters 43. The lifters 43 lift and lower the article transport vehicles 1 between the first layer path 41 and the second layer path 42. In some embodiments, for example, the bypass path 4 may include no first layer path 41, and the lifters 43 may lift and lower the article transport vehicles 1 between the primary path 3 and the second layer path 42. In this structure, each lifter 43 is included in the branching portion 91 or the joining portion 92.
(5) In the above embodiments, the bypass path 4 includes the lifters 43. In some embodiments, the bypass path 4 may include, in addition to the lifters 43 or in place of each lifter 43, an inclined path inclined with respect to the horizontal direction.
(6) In the above embodiments, the departure area A1 is set to include the entire portion of the departure path 32A, and the destination area A2 is set to include the entire portion of the destination path 32B. In some embodiments, for example, the departure area A1 may be set to include one station 8 on the departure path 32A, and the destination area A2 may be set to include one station 8 on the destination path 32B.
(7) The structure described in each of the above embodiments may be combined with any other structures described in the other embodiments unless any contradiction arises. The embodiments described herein are merely illustrative in all aspects and may be modified variously as appropriate without departing from the spirit and scope of the disclosure.

### Overview of Embodiment

An overview of the article transport facility described above will be described below.

An article transport facility includes a plurality of article transport vehicles that move along a travel path predefined to transport articles, and a control device that controls the plurality of article transport vehicles. The travel path includes a primary path and a bypass path. The primary path includes a plurality of stations at which the plurality of article transport vehicles stop, and a plurality of path intersecting portions in which paths intersect. The bypass path is connected to the primary path at a plurality of joints set on the primary path. The control device selects, using a path cost including a distance cost being higher for a greater distance by which the plurality of article transport vehicles move and a structure cost being higher for a slower speed at which the plurality of article transport vehicles move based on a structure of the travel path, a candidate route having the path cost being lowest from a plurality of candidate routes along which a target vehicle being one of the plurality of article transport vehicles is movable from a departure point to a destination point on the travel path. The control device adjusts, when a predetermined determination condition is satisfied in selecting the candidate route, the path cost of a candidate route of the plurality of candidate routes following the bypass path to be lower than a path cost used when the predetermined determination condition is unsatisfied.

In this structure, when the predetermined determination conditions are satisfied, a candidate route following the bypass path is more likely to be selected as a route for moving the target vehicle from the departure point to the destination point. This increases the number of article transport vehicles traveling on the bypass path when, for example, more article transport vehicles can travel on the primary path, and the article transport vehicles are more likely to be distributed on the primary path and the bypass path. Thus, this structure allows selection of an appropriate route from the multiple candidate routes, and facilitates the article transport efficiency of the entire article transport facility.

The predetermined determination condition may include a movement distance index being greater than or equal to a predetermined first threshold. The movement distance index may be an index of a distance for the plurality of article transport vehicles to move from the departure point to the destination point.

For an article transport vehicle that is to move by a short distance from the departure point to the destination point, a candidate route following the primary path is normally more likely to be selected. When the distance from the departure point to the destination point is greater as well, selecting the candidate route following the primary path at a higher rate is likely to cause the primary path to be congested with the article transport vehicles. In this structure, a candidate route following the bypass path is more likely to be selected for an article transport vehicle that is to move by a greater distance from the departure point to the destination point. Article transport vehicles are thus more likely to be distributed on the primary path and the bypass path.

In the above structure, the movement distance index may be a distance for the plurality of article transport vehicles to move along a candidate route of the plurality of candidate routes following the primary path alone and having the path cost being lowest.

In this structure, an appropriate movement distance index is used to appropriately determine determination conditions.

The predetermined determination condition may include a number of article transport vehicles of the plurality of article transport vehicles on the bypass path being less than or equal to a predetermined second threshold.

When a candidate route following the bypass path is likely to be selected with many article transport vehicles being on the bypass path, the bypass path may be congested. Although the bypass pass may not be congested, the article transport vehicles moving on the bypass path may reach the destination point late. The above structure can eliminate this issue and allows the article transport vehicles to be distributed on the primary path and the bypass path.

The predetermined determination condition may include a preset combination of an area including the departure point and an area including the destination point.

In this structure, when article transport vehicles moving through the primary path between particular areas are likely to cause congestion, a combination of the particular areas can be preset. When a combination of an area including the departure point and an area including the destination point matches the preset combination, a candidate route following the bypass path is more likely to be selected. This can reduce congestion with the article transport vehicles moving between the particular areas and facilitate the article transport efficiency of the entire article transport facility.

The predetermined determination condition may include at least a part of a reference candidate route being congested with the plurality of article transport vehicles or a number of article transport vehicles of the plurality of article transport vehicles on the reference candidate route being greater than or equal to a predetermined third threshold. The reference candidate route may be a candidate route of the plurality of candidate route following the primary path alone and having the path cost being lowest.

In this structure, when a candidate route following the primary path is congested or is potentially congested, the candidate route is less likely to be selected. A candidate route following the bypass path is thus more likely to be selected. This can reduce congestion with the article transport vehicles and facilitate the article transport efficiency in the article transport facility.

The bypass path may include a second layer path and a lifter. The second layer path may be installed at a second height different from a first height at which the primary path is set. The lifter may lift and lower the plurality of article transport vehicles between the first height and the second height. The structure cost may include a cost reflecting a slower moving speed of the plurality of article transport vehicles being lifted and lowered by the lifter.

The bypass path including the lifter for lifting and lowering the article transport vehicles typically has a higher path cost, and a candidate route following the primary path is more likely to be selected. With the bypass path including the lifter, however, the cost adjustment process described above can effectively allow the article transport vehicles to be distributed on the primary path and the bypass path.

### INDUSTRIAL APPLICABILITY

The technique according to one or more embodiments of the disclosure can be used in an article transport facility including multiple article transport vehicles that move along a predefined travel path to transport articles and a control device that controls the article transport vehicles.

1. An article transport facility, comprising:
a plurality of article transport vehicles configured to move along a travel path predefined to transport articles; and
a control device configured to control the plurality of article transport vehicles, and
wherein:
the travel path comprises:
a primary path comprising a plurality of stations at which the plurality of article transport vehicles stop and a plurality of path intersecting portions in which paths intersect, and
a bypass path comprising at least the plurality of stations fewer than the plurality of stations in the primary path or the plurality of path intersecting portions fewer than the plurality of path intersecting portions in the primary path per unit distance,
the bypass path is connected to the primary path at a plurality of joints set on the primary path,
the control device is configured to select, using a path cost including a distance cost that is higher for a greater distance by which the plurality of article transport vehicles move and a structure cost that is higher for a slower speed at which the plurality of article transport vehicles move based on a structure of the travel path, a candidate route having the path cost that is lowest from a plurality of candidate routes along which a target vehicle that is one of the plurality of article transport vehicles is movable from a departure point to a destination point on the travel path,
the control device is configured to adjust, when a predetermined determination condition is satisfied in selecting the candidate route, the path cost of a candidate route of the plurality of candidate routes following the bypass path to be lower than a path cost used when the predetermined determination condition is unsatisfied.

2. The article transport facility according to claim 1, wherein:
the predetermined determination condition includes a movement distance index that is greater than or equal to a predetermined first threshold, and the movement distance index is an index of a distance for the plurality of article transport vehicles to move from the departure point to the destination point.

3. The article transport facility according to claim 2, wherein:
the movement distance index is a distance for the plurality of article transport vehicles to move along a candidate route of the plurality of candidate routes following the primary path alone and having the path cost that is lowest.

4. The article transport facility according to claim 1, wherein:
the predetermined determination condition includes a number of article transport vehicles of the plurality of article transport vehicles on the bypass path that is less than or equal to a predetermined second threshold.

5. The article transport facility according to claim 1, wherein:
the predetermined determination condition includes a preset combination of an area including the departure point and an area including the destination point.

6. The article transport facility according to claim 1, wherein:
the predetermined determination condition includes at least a part of a reference candidate route that is congested with the plurality of article transport vehicles or a number of article transport vehicles of the plurality of article transport vehicles on the reference candidate route that is greater than or equal to a predetermined third threshold, and the reference candidate route is a candidate route of the plurality of candidate route following the primary path alone and having the path cost that is lowest.

7. The article transport facility according to claim 1, wherein:
the bypass path comprises a layer path and a lifter, the layer path is installed at a second height different from a first height at which the primary path is set, and the lifter lifts and lowers the plurality of article transport vehicles between the first height and the second height, and
the structure cost includes a cost reflecting a slower moving speed of the plurality of article transport vehicles that is lifted and lowered by the lifter.
